(19) United States
(12) Patent Application Publication
(10) Pub. No.: US 2014/0370216 A1
(43) Pub. Date: Dec. 18, 2014

(54) CASE STRUCTURE FOR AN ELECTRONIC DEVICE AND MANUFACTURING METHOD THEREOF

(71) Applicants: Inventec(Pudong) Technology Corporation, Shanghai (CN); Inventec Corporation, Taipei (TW)

(72) Inventors: Yi-Lun CHENG, Taipei (TW); Chun-Lung LIN, Taipei (TW); Chih-Ming WENG, Taipei (TW)

(73) Assignees: Inventec(Pudong) Technology Corporation, Shanghai (CN); Inventec Corporation, Taipei (TW)

(21) Appl. No.: 14/249,115

(22) Filed: Apr. 9, 2014

(30) Foreign Application Priority Data
Jun. 17, 2013 (CN) 201310239723.2

(51) Int. Cl. B29C 45/00; B29C 45/16; B32B 3/18; B32B 27/36; B32B 25/14; H05K 5/00; B32B 25/08

(52) U.S. Cl. CPC B29C 45/0003; H05K 5/0086; B29C 45/16; B32B 25/08; B32B 27/365; B32B 25/14; B32B 3/18; B29C 2045/0089; B29L 2009/00
USPC 428/36.4; 264/255

(57) ABSTRACT

A method for a case for an electronic device is provided. The method includes two steps. More specifically, in the method, a first plastic layer is formed by injection molding. Subsequently, a PCM microcapsule layer is formed on one side of the first plastic layer by injection molding.

### CROSS-REFERENCE TO RELATED APPLICATIONS

This non-provisional application claims priority under 35 U.S.C. §119(a) on Patent Application No(s). 201310239723.2 filed in China, P.R.C. on Jun. 17, 2013, the entire contents of which are hereby incorporated by reference.

### BACKGROUND OF THE INVENTION

1. Technical Field of the Invention

The disclosure relates to a case structure for an electronic device and manufacturing method thereof, more particularly to a case structure for an electronic device formed by injection molding and the manufacturing method thereof

2. Description of the Related Art

As technology advances and high-tech industries develop, the market competition for electronic devices (e.g., laptops, mobile phones, tablets, electronic dictionaries or portable game consoles) is more intense. In order to satisfy the customers' requirements for the performance of the electronic devices, in related industries invest a large amount of money on the research and development for improving the performance of the electronic devices. As a result, the performance of the electronic devices improves incessantly.

Since the performance of the electronic devices has been improved, the heat generated by the electronic devices has increased. In order to eliminate the heat from the electronic devices, the aluminum foil and the graphite sheet are usually attached on the case made by plastic, so as to perform the heat dissipation. However, this approach requires additional working which increases the cost in the production line. Furthermore, since the shapes of the cases vary, the aluminum foil and the graphite sheet cannot be attached to the case evenly, and this affects the heat dissipation result negatively. Hence, how to manufacture a case without the additional processing of the aluminum foil and the graphite sheet is a problem needed to be solved by the related industries.

### SUMMARY OF THE INVENTION

A method for a case for an electronic device is disclosed. In the method, a first plastic layer is formed by injection molding. A PCM (phase change material microcapsule) layer is formed on one side of the first plastic layer.

The disclosure further provides a case structure for an electronic device comprising a first plastic layer and a PCM microcapsule layer. The PCM microcapsule layer is disposed on one side of the first plastic layer.

### BRIEF DESCRIPTION OF THE DRAWINGS

The present disclosure will become more fully understood from the detailed description given herein below for illustration only, and thus does not limit the present disclosure, wherein:

FIG. 1 is a flow chart of a method for forming a case for an electronic device according to the first embodiment of the disclosure;

FIG. 2 is a schematic view of forming the first plastic layer in the method according to the first embodiment of the disclosure;

FIG. 3 is a schematic view of forming the PCM (phase change material) microcapsule layer in the method according to the first embodiment of the disclosure;

FIG. 4 is the front view of the structure of the PCM microcapsule according to the first embodiment of the disclosure.

FIG. 5 is the front view of the case structure for the electronic device according to the first embodiment of the disclosure;

FIG. 6 is a flow chart of a method for forming a case for an electronic device according to the second embodiment of the disclosure;

FIG. 7 is a schematic view of forming the second plastic layer in the method according to the second embodiment of the disclosure; and

FIG. 8 is the front view of the case structure for the electronic device according to the second embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

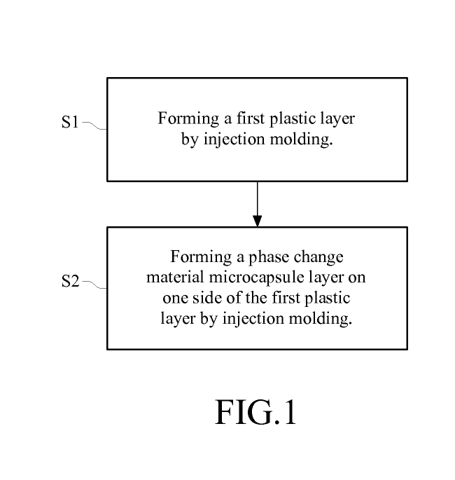

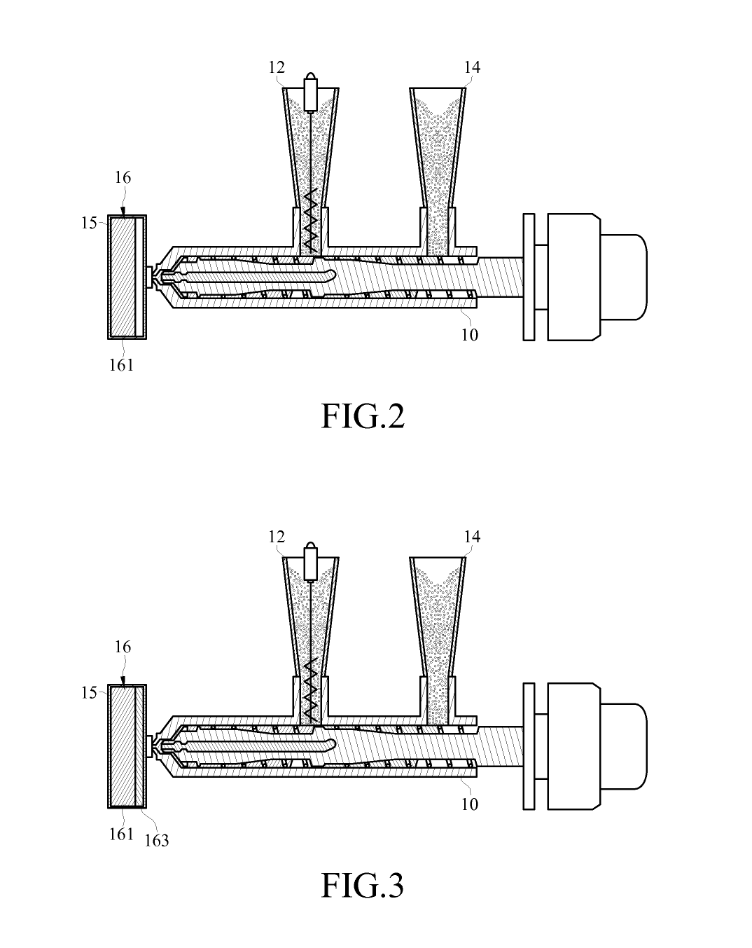

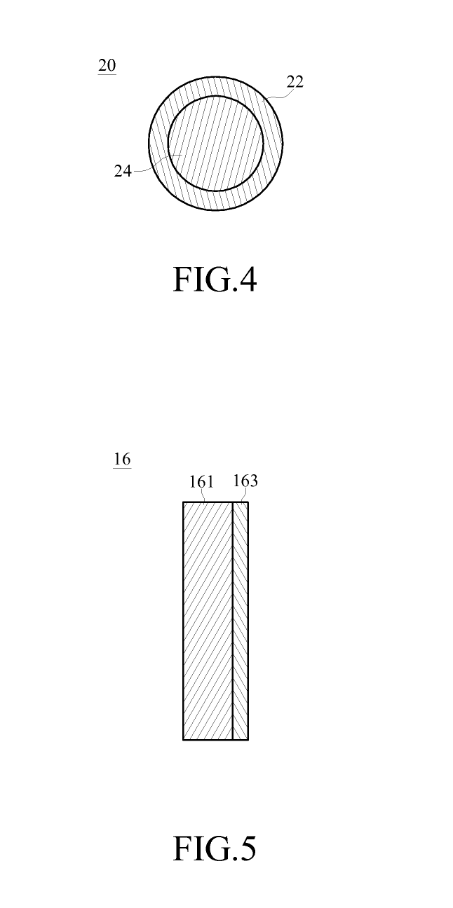

Referring to FIG. 1 to FIG. 4, FIG. 1 is a flow chart of a method for forming a case for an electronic device according to the first embodiment of the disclosure; FIG. 2 is a schematic view of forming the first plastic layer in the method according to the first embodiment of the disclosure; FIG. 3 is a schematic view of forming the PCM (phase change material) microcapsule layer in the method according to the first embodiment of the disclosure; FIG. 4 is the front view of the structure of the PCM microcapsule according to the first embodiment of the disclosure.

The first embodiment of the disclosure provides a method for forming a case for an electronic device. The method comprises:

S1: Forming a first plastic layer by injection molding. Specifically, as shown in FIG. 2, the injection molding machine 10 makes the first plastic material 14 become the first plastic layer 161 and forms the first plastic layer 161 in the mold 15 by injection molding. In this embodiment, the material of the first plastic layer 161 (the first plastic material 14) is a mixture of polycarbonate and ABS resin, but the disclosure is not limited thereto.

S2: Forming a PCM microcapsule layer on one side of the first plastic layer by injection molding. Specifically, as shown in FIG. 3 and FIG. 4, the injection molding machine 10 makes a plurality of PCM microcapsules 20 become the PCM microcapsule layer 163 and forms the PCM microcapsule layer 163 on one side of the first plastic layer 161. In this embodiment, the PCM microcapsule layer 163 comprises a plurality of PCM microcapsules 20. The PCM microcapsules 20 each comprises a capsule shell 22 and a capsule core 24. The capsule core 24 is located inside the capsule shell 22. Preferably, the capsule core 24 is enclosed by the capsule shell 22. The material of the capsule shell 22 is a high polymer, and the material of the capsule core 24 is a PCM. The melting point of the PCM is between 20° C. and 75° C., preferably between 35° C. and 55° C. In this embodiment, the high polymer forming the case shell 22 is a mixture of polycarbonate and glass fiber. The PCM forming the case core 24 is a heat absorbing substance, such as alkanes (e.g. icosane to triacontane), alcohols (e.g. decan-1-ol to icosane-1-ol), acids (e.g. decanoic acid to icosanoic acid) or paraffin. However, the material and the composition of the capsule shell 22 and the capsule core 24 are not limited to the disclosure. In this embodiment, the diameter of the PCM microcapsules is between 0.1 and 1000 micrometers (μm), preferably between 10 and 30 micrometers, and more preferably between 20 and 30 micrometers. Since the first plastic material 14 is a mixture of polycarbonate and ABS resin, and the melting of the mixture of polycarbonate and ABS resin is about 230° C. By comparison, the melting point the mixture of polycarbonate and glass fiber which forms the capsule shell 22 is about 285° C. In other words, the melting point of the capsule shell 22 is higher than the melting point of the first plastic material 14. Consequently, when the PCM microcapsules 20 is undergone the injection molding process after the first plastic layer 161, the temperature, set for the first plastic layer 161 for the injection molding, of the injection molding machine 10 is lower than the melting point of the capsule shell 22. Thereby, structural integrity of the PCM microcapsules 20 can be maintained.

Moreover, the disclosure provides a case structure for the electronic device. Referring to FIG. 4 and FIG. 5, FIG. 5 is the front view of the case structure for the electronic device according to the first embodiment of the disclosure.

After the injection molding machine 10 forms the PCM microcapsule layer 163 on one side of the first plastic layer 161, the users may remove the case structure 16 for the electronic device from the mold 15. The case structure 16 for the electronic device comprises a first plastic layer 161 and a PCM microcapsule layer 163. The PCM microcapsule layer 163 is disposed on one side of the first plastic layer 161.

In the case structure for the electronic device and the manufacturing method thereof according to the first embodiment of the disclosure, the PCM microcapsule layer 163 is disposed on one side of the first plastic layer 161, and the PCM has a great latent heat. That is, the PCM is capable of absorbing a large amount of heat when phase is changing. Therefore, the heat dissipation performance of the case structure 16 for the electronic device is improved, and this approach does not require attaching the aluminum foil and the graphite sheet on the surface of the case. Thereby, the additional working cost caused by attaching the aluminum foil and the graphite sheet to the case surface, as mentioned in the related art, is eliminated.

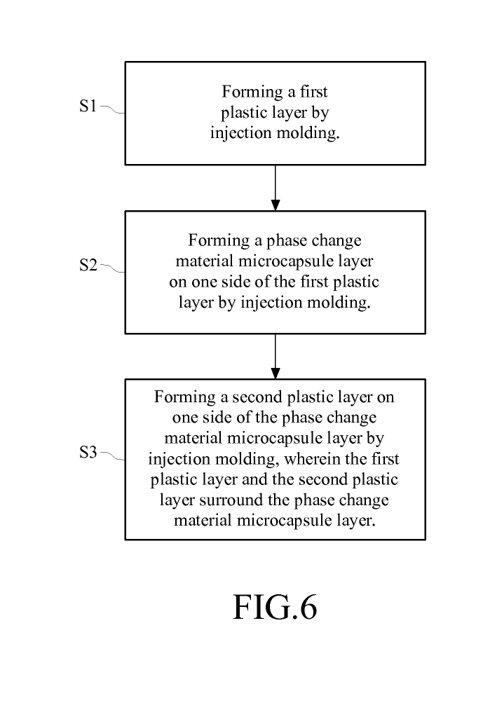

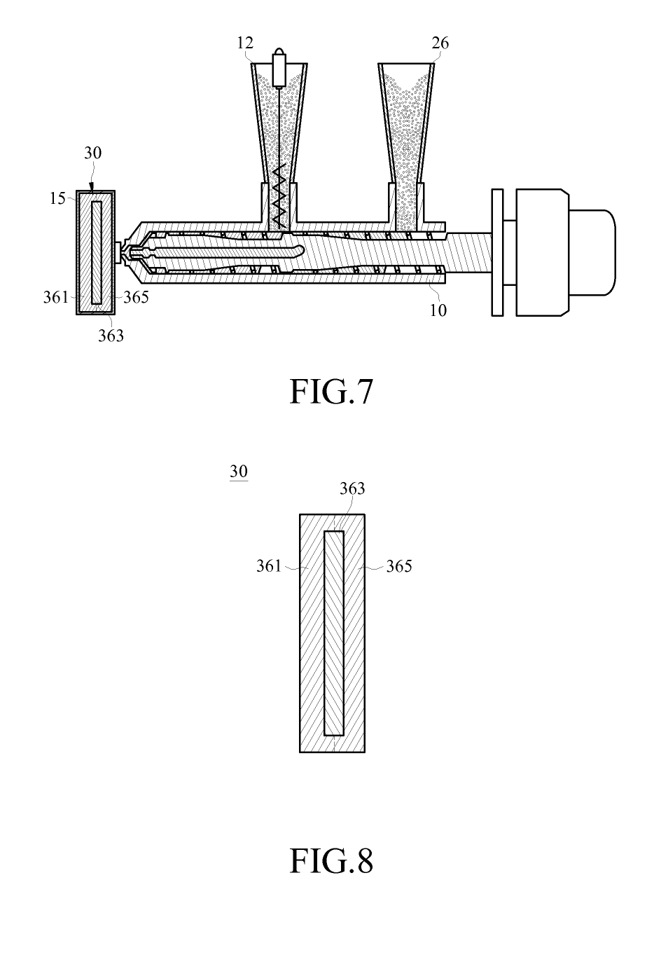

The second embodiment of the disclosure provides a manufacturing method for a case structure for an electronic device. Referring to FIG. 2, FIG. 3, FIG. 6 and FIG. 7, FIG. 6 is a flow chart of a method for forming a case for an electronic device according to the second embodiment of the disclosure; FIG. 7 is a schematic view of forming the second plastic layer in the method according to the second embodiment of the disclosure.

The manufacturing method for the case structure for the electronic device according to the second embodiment is similar to that in the first embodiment, wherein the difference is that a step S3 is added after FIG. 3. The Step S3 comprises: forming a second plastic layer on one side of the PCM microcapsule layer by injection molding, wherein the first plastic layer and the second plastic layer surround the PCM microcapsule layer. In this embodiment, the material of the second plastic layer is a mixture of polycarbonate and ABS resin, but the disclosure is not limited thereto.

Specifically, as shown in FIG. 7, the injection molding machine 10 make the second plastic material 26 become the second plastic player 365 and forms the second plastic player 365 on one side of the PCM microcapsule layer 363. The first plastic player 361 and the second plastic player 365 surround the PCM microcapsule layer 363.

Moreover, the second embodiment of the disclosure provides a case structure for the electronic device. Referring to FIG. 8, FIG. 8 is the front view of the case structure for the electronic device according to the second embodiment of the disclosure.

After the injection molding machine 10 forms the second plastic layer 26 on one side of the PCM microcapsule layer 363, the users may remove the case structure 30 for the electronic device from the mold 15. The case structure 30 for the electronic device comprises a first plastic layer 361, a second plastic layer 365 and a PCM microcapsule layer 363. The first plastic layer 361 and the second plastic layer 365 surround the PCM microcapsule layer 363.

In the case structure for the electronic device and the manufacturing method thereof according to the second embodiment of the disclosure, since the case structure 30 for the electronic device comprises the PCM microcapsule layer 363, and the PCM has a great latent heat. That is, the PCM is capable of absorbing a large amount of heat when phase is changing. Therefore, the heat dissipation performance of the case structure 30 for the electronic device is improved, and this approach does not require attaching the aluminum foil and the graphite sheet on the surface of the case. Thereby, the additional working cost caused by attaching the aluminum foil and the graphite sheet to the case surface, as mentioned in the related art, is eliminated.

In the case structure for the electronic device and the manufacturing method thereof according to the above-mentioned embodiments, since the case structure for the electronic device comprises the PCM microcapsule layer, the heat dissipation performance can be improved. Furthermore, this approach does not require attaching the aluminum foil and the graphite sheet to the case surface. Thereby, the additional working cost of attaching the aluminum foil and the graphite sheet can be eliminated.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method for a case for an electronic device, comprising steps of:
forming a first plastic layer by injection molding; and
forming a PCM (phase change material) microcapsule layer on one side of the first plastic layer by injection molding.

2. The method according to claim 1, wherein the PCM microcapsule layer comprises a plurality of PCM microcapsules, the plurality of PCM microcapsules each comprises a capsule shell and a capsule core, the capsule core is enclosed by the capsule shell, the capsule shell comprises a polymer, and the capsule core comprises a phase change material.

3. The method according to claim 2, further comprising a step of forming a second plastic layer on one side of the PCM microcapsule layer by injection molding, wherein the first plastic layer and the second plastic layer surround the PCM microcapsule layer.

4. The method according to claim 2, wherein the melting point of the capsule shell is higher than the melting point of the first plastic layer.

5. The method according to claim 2, wherein the polymer is a mixture of polycarbonate and glass fiber, and the phase change material comprises paraffin or alkanes.

6. The method according to claim 3, wherein the first plastic layer and the second plastic layer comprises a mixture of polycarbonate and ABS resin.

7. A case structure for an electronic device comprising:
a first plastic layer; and
a PCM microcapsule layer disposed on one side of the first plastic layer.

8. The case structure for the electronic device according to claim 7, wherein the PCM microcapsule layer comprises a plurality of PCM microcapsules, the plurality of PCM microcapsules each comprises a capsule shell and a capsule core, the capsule core is enclosed by the capsule shell, the capsule shell comprises a polymer, and the capsule core comprises a phase change material.

9. The case structure for the electronic device according to claim 8, further comprising a second plastic layer disposed on one side of the PCM microcapsule, wherein the first plastic layer and the second plastic layer surround the PCM microcapsule layer.

10. The case structure for the electronic device according to claim 8, wherein the melting point of the capsule shell is higher than the melting point of the first plastic layer.
